(19) United States
(12) Patent Application Publication
(10) Pub. No.: US 2018/0015766 A1
(43) Pub. Date: Jan. 18, 2018

(54) High Definition Stencils With Easy to Clean Properties for Screen Printing

(71) Applicant: Photo Stencil, LLC, Golden, CO (US)

(72) Inventor: Guocun Chen, Lakewood, CO (US)

(21) Appl. No.: 15/241,509

(22) Filed: Aug. 19, 2016

Related U.S. Application Data
(60) Provisional application No. 62/209,437, filed on Aug. 25, 2015.

(51) Int. Cl. B41N 1/24; C23C 14/00

(52) U.S. Cl. CPC B41N 1/24; C23C 14/00

(57) ABSTRACT

This invention is for production of a screen printing stencil system with hard nickel or nickel-cobalt base metal foil (10) with amorphous carbon nanocomposite intermediate layer having low coefficient of friction (30) and alternative layers of amorphous carbon nanocomposite (41) and amorphous fluorocarbon (42) optimized for its wettability in broad contact areas between squeegee blade and the stencil and oleophobic amorphous fluorocarbon-rich coatings (43) on the inner walls of through holes (20) and (21) to provide easy release of solder paste or metallic paste for high definition screen plating of small feature dimensions and easy to clean properties.

US Patent Documents

| | | |
|---|---|---|
| (1) 20130220152 | Febuary 2013 | K. Shibusawa |
| (2) 6228471 B1 | May 2001 | Neerinck et al |

### FIELD OF APPLICATION

This invention is about to produce a screen printing stencil system with layered structures of amorphous carbon nanocomposite and amorphous fluorocarbon coatings for high dimensional definition and easy to clean properties.

### BACKGROUND OF THE INVENTION

As the feature dimensions of printed circuit boards (PCB) become smaller, it would be most desirable to produce these features with stencils which apply solder or metallic paste with high definition without bleeding out the paste and high positional accuracy without stretching. Current stainless steel and pure nickel stencils are too ductile to meet such requirements because they are more vulnerable to stretching and deformation. They also tend to trap and bleed residual paste without oleophobicity. In particular, the paste with high viscosity is more difficult to produce smooth plate separation for high definition applications. Patent literature (1) discloses a method of manufacturing stencils with layered structures as follow: (a) an amorphous diamond carbon layer, (b) an organic silicon, oxygen and nitrogen intermediate layer for adhesion and, (3) oleophobic fluorine-containing silane coupling thin film on the inner walls of featured through holes, which is applied by dipping. Although this patent disclosure made broad claims for various stencil base metals, such as cast iron, aluminum, stainless steel, nickel and nickel alloys, it is not clear how these stencils are produced. More importantly, these metals are vulnerable to stretching and deformation which result in cracking or flaking off the amorphous carbon layer. Neither is it said how to protect the broad silicon-containing amorphous carbon areas from being coated when the fluorine-containing thin film is produced on the inner walls of the through holes. Additionally, the fluorine-containing thin film is too thin and soft for reliable operation of the stencils.

Apparently, patent literature (1) is unable to produce the stencils with high positional accuracy and enhanced definition for smaller features. In order to meet these requirements, the base metal stencils shall be able to retain the feature positions without stretching. They shall be made of metals and alloys harder than the current metals. The coating structure shall be readily produced with reasonable simplicity.

### THE OBJECTIVE OF THE INVENTION

The objective of this invention is to produce hard nickel and nickel-cobalt stencils (10) that are more resistant to stretching. Unique electroforming processes are developed to meet this requirement. A silicon containing amorphous carbon coating (30) is produced using the existing Dylyn amorphous carbon nanocomposite coating technology, see Patent Literature (2). On top of the Dylyn coating (30) and (31), alternative layers (40) of the Dylyn amorphous carbon nanocomposite (41) and fluorocarbon coatings (42) are produced so as to produce both the Dylyn nanocomposite layer (41) in contact areas with a squeegee blade for uniform paste distribution, and a durable fluorocarbon-rich top coating (43) on the inner walls of the featured through holes (20) and (21) for easy solder or metallic paste release.

### SUMMARY OF THE INVENTION

The increasing smaller features of PCBs demand the paste to be evenly and clearly printed via the featured through holes (20) and (21) of stencils (10). While the contact areas between the stencil and squeegee blade maintain sufficient wettability for paste distribution, the featured through holes (20) and (21) shall release the paste readily without bleeding out the paste in nearby areas. The positional accuracy requires the stencil to sustain its dimensions without stretching so that all of the designed features of PCBs are produced with high definition. These requirements are difficult to meet using existing technology.

The embodiments of this invention produce hard metal stencils that sustain their featured dimensions. The amorphous carbon nanocomposite coatings in contact areas have far lower coefficient of friction than those of existing stencils to provide stronger wear and scratching resistance. The fluorocarbon-rich coatings on the inner walls of the through holes (43) are oil-repellant to allow easy paste release.

One embodiment of this invention provides a method to produce hard nickel base stencil (10) by electroforming. A unique nickel-sulfamate plating solution is developed for this application. The solution has a moderate amount of surfactants to produce a satisfactory surface smoothness free of pits and pinholes. A moderate amount of brightener is added to the solution to enhance the surface smoothness. The additives incorporate carbon and sulfur into the stencil (10) to produce higher hardness than pure nickel that is typically produced in a nickel-sulfamate solution. The process is as the following: a pure nickel base layer is plated on a stainless steel mandrel to fill in minor scratches and small defects; a photoresist sheet laminated on the nickel base metal; the photoresist layer is masked with designed features of a PCB; exposed to an ultra-violet (UV) light; developed using a known developer; a dichromate conversion coating formed on the exposed portion of the base nickel; and then the hard nickel layer (10) electroformed on for a required thickness. After the hard nickel layer is grown, the photoresist is stripped off in a stripping solution. The hard nickel layer is then peeled off and used as a base stencil substrate (10) to be coated in a vacuum coating chamber. The vacuum coating is comprised of an intermediate amorphous carbon nanocomposite layer (30) and (31), alternative layers (40) of the amorphous carbon nanocomposite (41) and the amorphous fluorocarbon (42) in contact areas with squeegee blade, and fluorocarbon-rich top layer (43) on the inner walls of the featured through holes (20) and (21). The coating is produced using plasma assisted chemical vapor deposition (PACVD), physical vapor deposition (PVD), or filtered arc physical vapor deposition (FAPVD) as described in Patent Literature (2).

In another embodiment, a nickel-cobalt alloy stencil substrate (10) is produced using a unique nickel sulfate and cobalt sulfate plating solution by electroforming. This solution has suitable amount of additives to prevent pitting and pinholes and to produce satisfactory surface appearance. The base nickel plating and photolithographic processes are the same as those used for the hard nickel electroforming. The nickel-cobalt alloy stencil substrate (10) is then coated with an intermediate amorphous carbon nanocomposite layer (30) and (31), alternative layers (40) of the amorphous carbon nanocomposite (41) and the amorphous fluorocarbon (42) in contact areas with squeegee blade, and fluorocarbon-rich layer (43) on the inner walls of the featured through holes (20) and (21) using PACVD, PVD), or FAPVD.

### DESCRIPTION OF DRAWINGS

FIG. 1 a schematic showing the cross section of the layered structure of the stencil system.

### DETAILED DESCRIPTION OF THE EMBODIMENTS

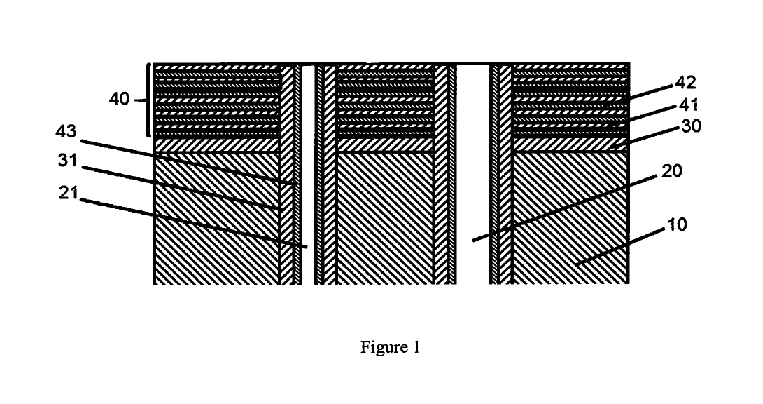

As shown in FIG. 1, the structure of the stencil is described in two embodiments as follows. In the first embodiment, the substrate stencil (10) is made of hard nickel by electroforming using a dedicated nickel-sulfamate solution. For two-dimensional stencils, the stainless steel mandrel is flat and polished to a grit 500 finish which has an average surface roughness (Ra) between 0.1 and 0.25 μm, preferably Ra is under 0.2 μm. For three-dimensional stencils, the stainless steel mandrels are polished to the same finish and then machined with pockets to enclosure the protruded chips on a PCB in designated areas. The mandrels are submerged in 25% wt to 36% wt nitric acid solution to remove residual metal debris, and then degreased by immersion in an alkaline degreaser. Subsequently, a nickel strike layer is plated on a mandrel in Woods nickel strike solution. This nickel strike solution has 220 g/l nickel chloride hexahydrate (NiCl₂.6H₂O) and 110 ml/l hydrochloric acid (HCl). Pure nickel anode rods have an oval shaped cross section about 25.4 mm thick, 76.2 mm wide and 660.4 mm long. Normally, six such nickel anode rods are placed in the nickel strike tank to provide uniform current distribution. The solution temperature is between 32 and 60° C., preferably between 40 and 52° C. The plating current density is between 80 and 100 A/dm². The nickel strike layer is plated for 7 to 10 minutes up to a thickness between 300 Å to 500 Å. After the nickel strike layer is plated to provide a layer for adhesion, the mandrel is transferred to the nickel-sulfamate solution. Porous nickel rounds are packed in titanium anode baskets. The back surface of the mandrel is covered with a polyvinyl chloride (PVC) sheet to prevent from being plated. The nickel sulfamate solution has a nominal pH of 4.2, with 300 to 450 g/l, preferable between 320 and 380 g/l nickel sulfamate tetrahydrate (Ni(SO₃NH₂)₂.4H₂O), 30 to 60 g/l, preferably between 35 and 45 g/l NiCl₂.6H₂O, and 30 to 45 g/l boric acid (H₃BO₃). A small amount of wetting reagents and surfactants are added to prevent pitting and pinholes, which are the common additives typically used in nickel plating.

Additionally, a small amount of saccharin sodium salt, between 0.10 and 1.0 g/l, is added to the nickel sulfamate solution to produce a satisfactory surface appearance. The solution temperature is between 38 and 60° C. Depending on the design requirements, the plating current density is between 120 and 450 A/dm², preferably between 150 and 420 A/dm². Normally, this nickel layer is about 25 μm thick to cover minor scratches and other surface defects to grow the subsequent stencil layer. After the base nickel layer is plated, the mandrel is laminated with a photoresist film, patterned in accordance with the design of a PCB, exposed to UV light, developed, and then sent back to electroform the hard nickel stencil layer (10). The mandrel is submerged in a dichromate solution to form a conversion coating prior to electroforming.

The hard nickel solution for electroforming is comprised of nickel sulfamate, nickel chloride, boric acid, and organic additives for wetting and brightening. The pH of the solution is maintained between 3.50 and 4.50, most desirably between 3.75 and 4.25, adjusted using sulfumic acid and nickel carbonate. The nickel sulfamate concentration is between 250 and 450 g/l, preferably between 300 and 375 g/l of Ni(SO₃NH₂)₂.4H₂O. The nickel chloride concentration is between 15 and 60 g/l, and preferably between 25 and 45 g/l NiCl₂.6H₂O, and the boric acid between 35 and 50 g/l. Saccharin sodium salt is added as a carrier and brightener at the concentration between 1.0 and 4.0 g/l, preferably between 1.5 and 3.0 g/l. 2-Butyne-1,4-diol is used for leveling with a concentration range between 0.05 and 1.0 g/l. Other surfactants are polyol and aliphatic alcohol in the concentration range between 0.01 and 0.2 g/l. The surface tension is maintained between 26.0 and 32.0 dyne/cm, preferably between 27 and 30 dyne/cm. Anodes are nickel rounds in titanium baskets evenly placed in front of the mandrel. The back surface of the mandrel is covered with a PVC sheet. The solution temperature is between 32 and 60° C., preferably between 46 and 60° C. A nominal plating current is between 120 and 500 A/dm², preferably between 150 and 450 A/dm². Variable thickness of stencils is produced, from 10 to 200 μm. After the photoresist inside the featured through holes (20) of the stencil is stripped off in an industrial stripping solution, the stencil (10) is peeled off. The microhardness of the stencils is between 440 and 520 Vickers (Hv).

In another embodiment, a nickel-cobalt solution is used to electroform the stencils (10). The mandrels with nickel-sulfamate plated base metal are processed in photolithography, submerged in the dichromate solution to form conversion coatings, and then electroformed. This solution has about 200 to 360 g/l, preferably between 220 and 300 g/l nickel sulfate, and 25 to 50 g/l, preferably 30 to 45 g/l cobalt sulfate heptahydrate (CoSO₄.7H₂O), 25 to 60 g/l NiCl₂.6H₂O, and 35 to 50 g/l boric acid. The pH of the solution is maintained between 3.50 and 4.50, preferably between 3.75 and 4.25, adjusted by sulfuric acid and nickel carbonate. A saccharin sodium salt is used for brightening, with a concentration range between 1.5 to 3.0 g/l. Leveling reagents and pitting inhibitors are 2-Butyne-1,4-diol and 1,3,(6,7)-naphthalenetrisulfonic acid trisodium salt. The 2-Butyne-1,4-diol concentration ranges from 0.1 to 1.0 g/l, and 1,3,(6,7)-naphthalenetrisulfonic acid trisodium from 0.25 to 4.0 g/l. Additional surfactants are polyethylene glycol (PEG, 10 to 80 ml/l) and sodium dodecyl sulfate (SDS, 0.05 to 1.0 g/l). The surface tension is maintained between 27.0 and 32.0 dyne/cm, desirably between 28.0 and 30.0 dyne/cm. No metallic cobalt anode is used. Nickel rounds are packed in titanium baskets and evenly placed in front of the mandrel with optimized spacing. The solution temperature is between 38 and 60° C., preferably between 52 and 60° C. The back surface of the mandrel is covered with a polyvinyl chloride (PVC) sheet. Plating current density is between 150 and 450 A/dm². Stencils (10) are formed with 25 to 35% wt cobalt in this current range with microhardness between 520 and 580 Hv.

After the hard nickel and nickel-cobalt stencils (10) are produced, they are placed in a vacuum deposition chamber. A Dylyn amorphous carbon nanocomposite coating (30) and (31) is deposited using PACVD, PVD or FAPVD process as described in Patent Literature (2). The vacuum chamber is evacuated to a base pressure around 1.0×10⁻³ Pa, heated to a temperature between 80 and 200° C., and then a liquid siloxane precursor such as hexamethydisiloxane (HMDSO) is delivered into the chamber at a controlled flow rate using argon as a carrier gas. The deposition pressure is between 0.1 and 1 Pa. The deposition rate is about 2 μm/hour. The amorphous carbon nanocomposite coating (30) and (31) is comprised of a-C:H and a-Si:O. The coating thickness is between 0.1 and 1.0 μm, desirably between 0.20 and 0.5 μm. After the target thickness is reached, a fluorocarbon precursor is introduced into the chamber at a pulsed flow rate meanwhile the HMDSO flow rate is reduced to 0 to 75% of the previous nominal flow. The fluorocarbon may be any of the fluoroalkyl gases such as trifluoromethane, tetrafluoromethane, hexafluoroethane or octafluoropropane. The fluorocarbon gas is delivered to the vacuum chamber at 20 to 100 standard cubic centimeters per minute (sccm). Its flow rate is pulsed against the HMDSO flow at 30 to 150 seconds on-and-off frequency. When the pulse of the fluorocarbon gas flow is off, the HMDSO is delivered at its nominal rate between 20 and 100

1. (canceled)

2. (canceled)

3. (canceled)

4. (canceled)

5. (canceled)

6. The process for manufacturing of the stencil system comprising the steps of
a. plating a base nickel layer in a nickel sulfamate solution for enhanced surface smoothness;
b. develop the designed features of a PCB through photolithographic process on the base nickel layer;
c. electroforming the hard nickel or nickel-cobalt stencil base metal (10) in the said solutions;
d. deposition of the said intermediate amorphous carbon a-C:H and a-Si:O, nanocomposite layer (30) and (31) in a vacuum chamber using PACVD, PVD, and FAPVD technology; and
e. deposition of the said alternative layers of alternative layers (40) of hydrophilic a-C:H and a-Si:O nanocomposite (41) and fluorinated a-C:H and a-Si:O (42).
f. deposition of the said fluorocarbon-rich top layer (43) on the inner walls of the featured through holes (20) and (21).

7. A substrate stencil comprising:
a metal substrate including nickel or a nickel-cobalt alloy and forming at least one aperture, the metal substrate having microhardness in range between 440 and 580 Vickers.

8. The substrate stencil of claim 7, the metal substrate consisting essentially of nickel and having microhardness in range between 440 and 520 Vickers.

9. The substrate stencil of claim 7, the metal substrate consisting essentially of nickel-cobalt alloy containing between 25% and 35% cobalt and having microhardness in range between 520 and 580 Vickers.

10. The substrate stencil of claim 7, the at least one aperture spanning from a first side of the substrate stencil to a second side of the substrate stencil, the first side further including a first amorphous nanocomposite layer deposited on the metal substrate.

11. The substrate stencil of claim 10, the amorphous nanocomposite layer consisting essentially of a-C:H and a-Si:O.

12. The substrate stencil of claim 10, the first side further including alternating layers of amorphous carbon nanocomposite coating and amorphous fluorocarbon-based coating.

13. The substrate stencil of claim 12, the amorphous carbon nanocomposite coating being hydrophilic.

14. The substrate stencil of claim 13, the amorphous carbon nanocomposite coating consisting essentially of a-C:H and a-Si:O, the amorphous fluorocarbon-based coating consisting essentially of fluorinated a-C:H and a-Si:O.

15. The substrate stencil of claim 12, further comprising, for each aperture, a second amorphous nanocomposite layer and a fluorocarbon-rich coating lining the aperture, the second amorphous nanocomposite layer being deposited on inner walls of the metal substrate surrounding the aperture, the fluorocarbon-rich coating being deposited over the second amorphous nanocomposite layer to surround the aperture and span between the first and second sides.

16. The substrate stencil of claim 15, the second amorphous nanocomposite layer consisting essentially of a-C:H and a-Si:O.

17. The substrate stencil of claim 15, thickness of each of the first amorphous nanocomposite layer and the second amorphous nanocomposite layer being between 0.1 and 1.0 microns.

18. The substrate stencil of claim 15, the fluorocarbon-rich coating being oleophobic.

19. The substrate stencil of claim 15, thickness of the fluorocarbon-rich coating being between 25 and 750 nm.

20. The substrate stencil of claim 12, total thickness of the alternating layers being between 0.1 and 1.0 microns.

21. The substrate stencil of claim 7, the metal substrate being formed by electroplating the nickel or a nickel-cobalt alloy in a nickel sulfamate solution.
